(19) United States
(12) Patent Application Publication
(10) Pub. No.: US 2009/0311615 A1
(43) Pub. Date: Dec. 17, 2009

(54) METHOD OF PHOTOLITHOGRAPHIC PATTERNING

(76) Inventor: Deming TANG, Shanghai (CN)

Correspondence Address: J C PATENTS, 4 VENTURE, SUITE 250, IRVINE, CA, 92618, US

(21) Appl. No.: 12/483,973

(22) Filed: Jun. 12, 2009

Related U.S. Application Data
(60) Provisional application No. 61/061,354, filed on Jun. 13, 2008.

(51) Int. Cl. G03F 7/20

(52) U.S. Cl. 430/30

(57) ABSTRACT

A method of photolithographic patterning mainly includes: converting a first photolithographic pattern by a digital transformation in a first magnification to a second photolithographic pattern; producing a first optical reticle corresponding to the second photolithographic pattern by an initial lithography in a 1-to-1 image transfer; fabricating a second optical reticle on a transparent substrate by a first photolithography in a first demagnification corresponding to the first optical reticle; and fabricating a microscopic pattern of same dimension as the first photolithographic pattern on a wafer substrate by a second demagnification using the second optical reticle. The multiplication of the first magnification by the first demagnification by the second demagnification equals one. The present invention implements fine patterning on a wafer substrate so as to improve efficiency of photolithographic application.

### CROSS-REFERENCE TO RELATED APPLICATIONS

This application claims priority of provisional application No. 61/061,354, filed on Jun. 13, 2008, entitled “Method of Fine Reticle Fabrication by Two-Step Lithography and Photolithographic Application”, which is incorporated herein by reference in its entirety.

### FIELD OF THE INVENTION

The present invention relates to a method of photolithographic patterning, particularly to a photolithography process in fabricating a micro device on a wafer substrate.

### BACKGROUND

Photolithography process is essential to the fabrication process for various micro devices such as semiconductor integrated circuits on a wafer substrate. Therein, a mask called a reticle, which is produced on an optically transmissive substrate, such as a quartz glass substrate, with a light shielding material such as chromium (Cr), is used as a master plate to replicate the design pattern of a desired semiconductor integrated circuit or microstructure. The existing photolithography technology generally employs a scheme of transferring a circuit pattern written on the reticle onto a semiconductor wafer with a photoresist applied thereto by reduction exposure.

A common method for creating a pattern on a reticle is by the use of an electronic beam writer, or the e-beam lithography, where an electron source produces many electrons that are accelerated and focused in the shape of a beam, or e-beam, toward the reticle. The e-beam is focused either magnetically or electrostatically and scanned in the desired pattern across a special e-beam resist on the reticle surface. Such e-beam resist is spin coated on a thin opaque metal film, such as chrome film, on a quartz glass substrate, and patterned as selectively exposed to e-beam and developed by thermal baking. The final ultra fine pattern is etched into the chromium film with a dry etch process. The remaining e-beam resist is then stripped, the reticle cleaned and coated with certain protecting and optical enhancement coating before being examined for defects and measured against to the original digital image pattern associated with an integrated circuit layout.

As circuit patterns to be written on reticles become extremely complex and of ultra fine resolution at a nanometer scale, the fabrication of a reticle itself also becomes extremely complicated and difficult. As the ultra fine patterning of the opaque film on a reticle is defined through the e-beam scanning exposure on a single unit process and thus each time, only a single reticle is made, it is very time consuming and inefficient with poor yield. As the e-beam writer becomes much more complicated for achieving ultra fine resolution and precision, the costs for producing nanometer scale reticles are skyrocketing.

### SUMMARY

One aspect of the present invention provides a method of photolithographic patterning in order to fabricate photolithographic reticles of ultra fine dimensions through two-step lithography and implement associated applications of those reticles in photolithographic process.

One embodiment of the present invention provides a method of photolithographic patterning including the following steps:
converting a first photolithographic pattern by a digital transformation in a first magnification to a second photolithographic pattern, the first photolithographic pattern and the second photolithographic pattern being in binary image data;
producing a first optical reticle corresponding to the second photolithographic pattern by an initial lithography in a 1-to-1 image transfer, the first optical reticle having a first fiducial alignment mark;
fabricating a second optical reticle on a transparent substrate by a first photolithography in a first demagnification corresponding to the first optical reticle, the second optical reticles having a second fiducial alignment mark corresponding to the first fiducial alignment mark; and
fabricating a microscopic pattern of same dimension as the first photolithographic pattern on a wafer substrate by a second demagnification using the second optical reticle, and the microscopic pattern having a third fiducial alignment mark corresponding to the second fiducial alignment mark.

The multiplication of the first magnification by the first demagnification by the second demagnification equals one.

One embodiment of the present invention fabricates a fine photolithographic reticle by two-step lithography, which simplifies fabrication procedure of a photolithographic reticle so that the costs for producing nanometer scale reticles are lowered. Besides, as the ultra fine patterning on a reticle is not defined through the e-beam scanning exposure on a single unit process, there is no need to make a single reticle each time so as to improve producing efficiency of photolithographic reticles. Further, the method of the present embodiment also implements fine patterning on a wafer substrate so as to improve efficiency of photolithographic application.

### BRIEF DESCRIPTION OF THE DRAWINGS

The accompanying drawings, which not to real proportion of real dimensions, are incorporated herein and form a part of the specification, illustrate embodiments of the present invention and, together with the description, further serve to explain the principles of the invention and enable a person skilled in the pertinent art to make and use the invention.

FIG. 1 shows a combined block and schematic diagram illustrating the method of photolithographic patterning in one embodiment of the present invention.

FIG. 2 shows a combined block and schematic diagram illustrating the method of photolithographic patterning in another embodiment of the present invention.

FIG. 3 shows a combined block and schematic diagram illustrating the method of photolithographic patterning in another embodiment of the present invention.

### DETAILED DESCRIPTION

The present invention is described in detail below through embodiments accompanied with drawings.

While the present invention is described herein with reference to illustrative embodiments for particular applications, it should be understood that the invention is not limited thereto. Those skilled in the art with access to the teachings provided herein will recognize additional modifications, applications, and embodiments within the scope thereof and additional fields in which the present invention would be of significant utility.

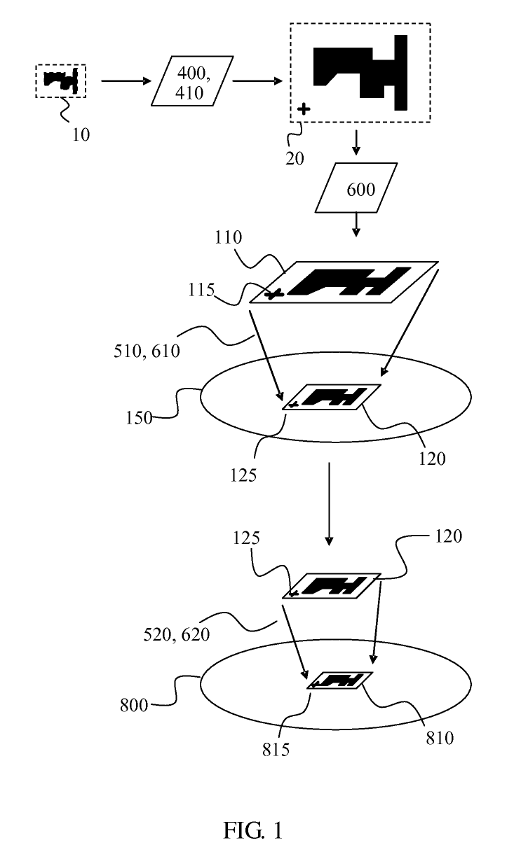

FIG. 1 shows a combined block and schematic diagram illustrating the method of photolithographic patterning in one embodiment of the present invention. In this method, a fine photolithographic reticle (i.e., a second optical reticle 120) is fabricated by two steps of lithography (i.e., an initial lithography 600 and a first photolithography 610). Besides, by applying the second optical reticle 120, through a second photolithography 620, a first layer of microscopic pattern 810 on a wafer substrate 800 according to a first lithographical pattern 10 in binary image data is fabricated. The method includes the following steps:

Step 11 is to convert a first photolithographic pattern 10 by a digital transformation 400 in a first magnification 410 to a second photolithographic pattern 20. The first photolithographic pattern 10 and the second photolithographic pattern 20 are both in binary image data.

The original photolithographic pattern (i.e., the first photolithographic pattern) 10 may be typically generated through a mask layout process in binary image data. The first photolithographic pattern 10 corresponds to the microscopic pattern 810 to be fabricated on a final target wafer substrate 800.

Step 12 is to produce a first optical reticle 110 corresponding to the second photolithographic pattern 20 by an initial lithography 600 in a 1-to-1 image transfer. The first optical reticle 110 has a first fiducial alignment mark 115.

The initial lithography 600 may be an electron-beam lithography commonly used for fabricating standard photolithographic reticles. The first fiducial alignment mark 115 is used for a succeeding first photolithography 610 on a transparent wafer substrate 150.

Step 13 is to fabricate a second optical reticle 120 on a transparent substrate 150 by a first photolithography 610 in a first demagnification 510 corresponding to the first optical reticle 110. The second optical reticle 120 has a second fiducial alignment mark 125 corresponding to the first fiducial alignment mark 115.

Specifically, the second photolithographic reticle 120 may be fabricated in the first demagnification 510 through photolithography equipment such as either step-and repeat stepper or step-and-scan system. the second photolithographic reticle 120 may have a plurality of duplicates on the transparent substrate 150. The transparent wafer 150 are then passivated and diced to individual second photolithographic reticles 120 which may be later assembled and tested. Such a second photolithographic reticle 120 contains the second fiducial alignment mark 125 inherent from the first fiducial alignment mark 115 on the first optical reticle 110. Typically in such photolithography equipment, the first demagnification 510 may be 2-to-1 to 10-to-1 exposure, preferably either 5-to-1 for stepper exposure or 4-to-1 for scanner exposure.

Step 14 is to fabricate a microscopic pattern 810 of same dimension as the first photolithographic pattern 10 on a wafer substrate 800 by a second demagnification 520 using the second optical reticle 120. The microscopic pattern 810 has a third fiducial alignment mark 815 corresponding to the second fiducial alignment mark 125.

Very typically, as in conventional photolithography wafer process, this step may be implemented by using either step-and repeat stepper or step-and-scan system. Again, the second demagnification 520 may also be 2-to-1 to 10-to-1 exposure, preferably either 5-to-1 for stepper exposure or 4-to-1 for scanner exposure. To replicate the microscopic pattern 810 on the final target wafer substrate 800 with the critical dimension and image identical to the original photolithographic pattern (i.e., the first photolithographic pattern) 10, the first magnification 410 multiplied by the first demagnification 510 multiplied by the second demagnification 520 has to be equal to numeric one. For example, if 4-to-1 demagnification is employed with scanner exposure for both the first demagnification 510 and the second demagnification 520, the magnification proportion of the first magnification 410 shall be 1-to-16 or 16×.

In addition, since the processing technology for semiconductor integrated circuits demands ultra fine fabrication of critical dimensions shrinking aggressively to nanometer scale per roadmap specified by the SIA (Semiconductor Industry Association), the rapid advancement of the micro fabrication technology demands illumination sources of shrinking wavelengths to be used at the time of exposing a circuit pattern written on a reticle onto a semiconductor wafer, from I-line, KrF and ArF DUV, and EUV. The photolithography technology that uses short-wavelength light sources, beyond KrF and ArF, has to employ ultra fine lithographic resolution techniques. Accordingly, in order to achieve a sufficient fine resolution, associated with two steps of photolithography in the demagnification 510 and the demagnification 520, appropriate optical proximity correction (OPC) may be incorporated in the digital transformation 400 for converting the first photolithographic pattern 10 to the second photolithographic pattern 20 in the first magnification 410 so as to accurately match a micro circuit pattern. Besides, if necessary, a process of phase-shift masking (PSM) may also be used.

Preferably for fabricating the second optical reticle 120 through the first photolithography 610, the transparent substrate 150 may be a quartz glass wafer of proper thickness as conventional photolithographic reticles. Meanwhile various opaque materials used in typical semiconductor fabrication process are available to be used for fabricating the required opaque thin film microstructures in the second optical reticle 120, including chrome, chrome oxide and chrome oxynitride, titanium, titanium nitride, rubidium, molybdenum and molybdenum silicide, tantalum and tantalum nitride, tungsten, and ruthenium. Specifically, stacked layers formed by a single above-mentioned opaque material or a combination of more than two above-mentioned opaque materials may be readily deposited on such a transparent substrate 150 by a process of either physical vapor deposition or chemical vapor deposition or a combination of physical vapor deposition and chemical vapor deposition, which may also be etched and patterned by photolithography referring to the first optical reticle 110.

The first optical reticle 110 fabricated through electron-beam lithography may further includes a certain available phase shifters in thin film microstructures to overcome photolithographic errors due to light diffraction. Similar thin film microstructures as phase shifters are also fabricated on the second optical reticle 120 in duplication on the transparent substrate 150 through the similar thin film deposition, photolithography and etching processes as part of the above for producing the second photolithographic reticle 120. Similar opaque materials are available for fabricating the phase shifter, including but not limited to: one or any combination of chrome, chrome oxide and chrome oxynitride, titanium, titanium nitride, tantalum and tantalum nitride.

The present embodiment fabricates a fine photolithographic reticle by two-step lithography, which simplifies fabrication procedure of a photolithographic reticle so that the costs for producing nanometer scale reticles are lowered. Besides, as the ultra fine patterning on a reticle is not defined through the e-beam scanning exposure on a single unit process, there is no need to make a single reticle each time so as to improve producing efficiency of photolithographic reticles. Further, the method of the present embodiment also implements fine patterning on a wafer substrate so as to improve efficiency of photolithographic application.

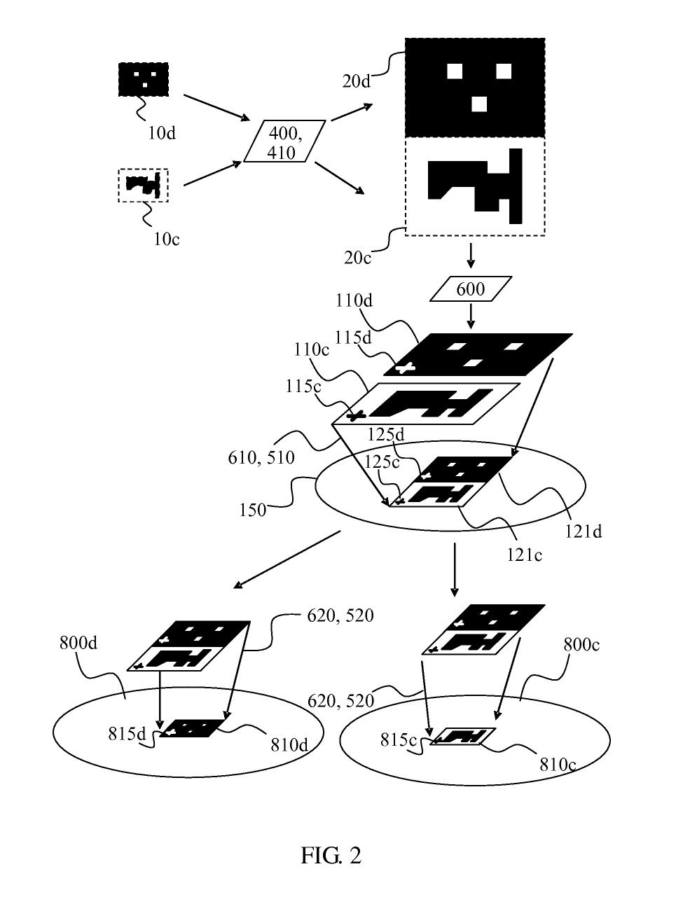

FIG. 2 shows a combined block and schematic diagram illustrating the method of photolithographic patterning in another embodiment of the present invention. In this method, a second photolithographic reticle 120 of fine dimensions is fabricated by two-step lithography. The second photolithographic reticle 120 contains two regions in two different optical tones (i.e., the second clear-field optical reticle 121c and the second dark-field optical reticle 121d) and associated photolithographic application of a selected one of two regions 121c and 121d to a wafer substrate 800 is implemented. The method includes the following steps:

Step 21 is to convert a first clear-field photolithographic pattern 10c to a second clear-field photolithographic pattern 20c and convert the first dark-field photolithographic pattern 10d to the second dark-field photolithographic pattern 20d by a digital transformation 400 in a first magnification 410.

In conventional photolithographic practice of wafer manufacture process, lithographic patterns are in general categorized to two classes, namely a clear-field photolithographic pattern in clear-field tone and a dark-field photolithographic pattern in dark-field tone. Because of difference in fabrication process, photolithographic patterns are thus separated and transformed onto different reticles per their optical tones. Different to the above embodiment, in the present embodiment, the first photolithographic pattern 10 includes a first clear-field photolithographic pattern 10c and a first dark-field photolithographic pattern 10d; the second photolithographic pattern 20 includes a second clear-field photolithographic pattern 20c and a second dark-field photolithographic pattern 20d.

Step 22 is to produce a first clear-field optical reticle 110c corresponding to the second clear-field photolithographic pattern 20c and a first dark-field optical reticle 110d corresponding to the second dark-field photolithographic pattern 20d by an initial lithography 600 in a 1-to-1 image transfer. The first clear-field optical reticle 110c has a first clear-field fiducial alignment mark 115c, and the first dark-field optical reticle 110d has a first dark-field fiducial alignment mark 115d.

Step 23 is to fabricate the second clear-field optical reticle 121c corresponding to the first clear-field optical reticle 110c and the second dark-field optical reticle 121d corresponding to the first dark-field optical reticle 110d on the transparent substrate 150 by the first photolithography 610. The second clear-field optical reticle 121c and the second dark-field optical reticle 121d are not overlapped and disposed one next to another side by side. The second clear-field optical reticle 121c has a second clear-field fiducial alignment mark 125c, and the second dark-field optical reticle 121d has a second dark-field fiducial alignment mark 125d.

Specifically, on the transparent substrate 150, a pair of second optical reticles (i.e., the second clear-field optical reticle 121c and the second dark-field optical reticle 121d) may be fabricated in duplication by the first photolithography 610 in the first demagnification 510, by exposing the first clear-field optical reticle 110c and the first dark-field optical reticle 110d disposed one next to another side by side on the transparent substrate 150 without overlapping. Duplicate sets of the second clear-field optical reticle 121c for the second clear-field photolithographic pattern 20c and the second dark-field optical reticle 121d for the second dark-field photolithographic pattern 20d are thus produced and assembled from one transparent substrate 150 through the aforementioned process.

Step 24 is to fabricate a clear-field microscopic pattern 810c of same dimension as the first clear-field photolithographic pattern 10c on a first wafer substrate 800c by a second photolithography 620 in the second demagnification 520 using the second clear-field optical reticle 121c, and fabricate a dark-field microscopic pattern 810d of same dimension as the first dark-field photolithographic pattern 10d on a second wafer substrate 800d by a second photolithography 620 in the second demagnification 520 using the second dark-field optical reticle 121d.

The clear-field microscopic pattern 810c has a third clear-field fiducial alignment mark 815c corresponding to the second clear-field fiducial alignment mark 125c, and the dark-field microscopic pattern 810d has a third dark-field fiducial alignment mark 815d corresponding to the second dark-field fiducial alignment mark 125d.

In the second photolithography 620 in the second demagnification 520, each of the second clear-field optical reticles 121c and each of the second dark-field optical reticles 121d may be separately used for fabricating the first clear-field photolithographic pattern 10a on the first wafer substrate 800c and the first dark-field photolithographic pattern 10d on the second wafer substrate 800d. Specifically, the first clear-field photolithographic pattern 10a may have a plurality of duplicates on the first wafer substrate 800c and the first dark-field photolithographic pattern 10d may also have a plurality of duplicates on the second wafer substrate 800d. And also in an extended embodiment of the present invention, a pair of the second clear-field optical reticle 121c and the second dark-field optical reticle 121d may be assembled as separate reticles from the transparent substrate 150 after the first photolithography 610 and used separately to different wafer substrates.

Furthermore, the digital transformation 400 and/or the second photolithography 620 may also include a process of optical proximity correction in the present embodiment so as to achieve a sufficient fine resolution which accurately matches a micro circuit pattern.

In addition to the advantages of the above embodiment, the present embodiment also implements the fabrication of a fine photolithographic reticle by two-step lithography containing two regions in two different optical tones, and implements associated photolithographic application of selected one of two patterns in different optical tones to different wafer substrates.

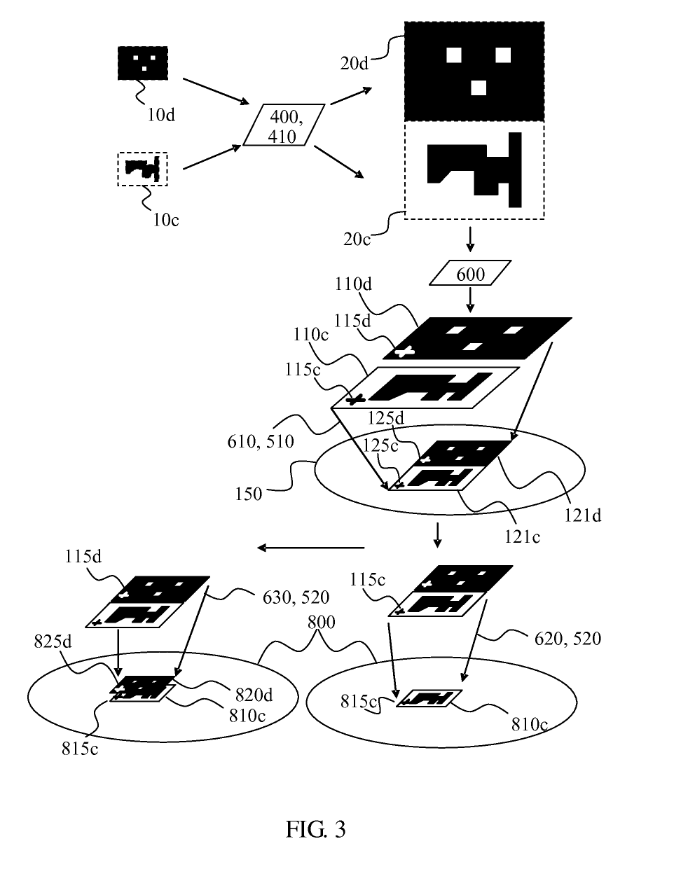

FIG. 3 shows a combined block and schematic diagram illustrating the method of photolithographic patterning in another embodiment of the present invention. In the method, a second photolithographic reticle 120 is fabricated by two-step lithography 600 and 610 containing two regions in two different optical tones (i.e., the second clear-field optical reticle 121c and the second dark-field optical reticle 121d) and associated photolithographic application to fabricate the two horizontally overlapped but vertically aligned clear-field microscopic pattern 810c and dark-field microscopic pattern 820d onto one wafer substrate 800. The method includes the following steps:

The steps 31-33 are same as the steps 21-23 illustrated in FIG. 2 respectively, which are not repeated here.

Step 34 is to fabricate a clear-field microscopic pattern 810c of same dimension as the first clear-field photolithographic pattern 10c on the wafer substrate 800 by a second photolithography 620 in the second demagnification 520 using the second clear-field optical reticle 121c, and fabricate a dark-field microscopic pattern 820d of same dimension as the first dark-field photolithographic pattern 10d on the wafer substrate 800 by a third photolithography 630 in the second demagnification 520 using the second dark-field optical reticle 121d.

The clear-field microscopic pattern 810c has a third clear-field fiducial alignment mark 815c corresponding to the second clear-field fiducial alignment mark 125c, and the dark-field microscopic pattern 820d has a fourth dark-field fiducial alignment mark 825d to the second dark-field fiducial alignment mark 125d. The dark-field microscopic pattern 820d is disposed above or under the clear-field microscopic pattern 810c horizontally overlapped. The third clear-field fiducial alignment mark 815c and the fourth dark-field fiducial alignment mark 825d are vertically aligned.

Furthermore, the digital transformation 400, the second photolithography 620 and/or the third photolithography 630 may also include a process of optical proximity correction in the present embodiment so as to achieve a sufficient fine resolution which accurately matches a micro circuit pattern.

In addition to the advantages of the above embodiments, the present embodiment also implements associated photolithographic application to fabricate the two horizontally overlapped but vertically aligned microscopic patterns as two independent layers onto one wafer substrate.

Such methods illustrated above in FIG. 2 and FIG. 3 in the above embodiments may be very commonly incorporated in the practice of multiple project wafer (MPW) and multiple layer masking (MLM) in semiconductor manufacturing.

While specific embodiments of the present invention have been described above, it should be understood that they have been presented by way of example only, and not limitation. It will be understood by those skilled in the art that various changes in form and details may be made therein without departing from the spirit and scope of the invention as defined in the appended claims. Thus, the breadth and scope of the present invention should not be limited by any of the above-described exemplary embodiments, but should be defined only in accordance with the following claims and their equivalents.

What is claimed is:

1. A method of photolithographic patterning comprising:
converting a first photolithographic pattern by a digital transformation in a first magnification to a second photolithographic pattern, the first photolithographic pattern and the second photolithographic pattern being in binary image data;
producing a first optical reticle corresponding to the second photolithographic pattern by an initial lithography in a 1-to-1 image transfer, the first optical reticle having a first fiducial alignment mark;
fabricating a second optical reticle on a transparent substrate by a first photolithography in a first demagnification corresponding to the first optical reticle, the second optical reticles having a second fiducial alignment mark corresponding to the first fiducial alignment mark;
fabricating a microscopic pattern of same dimension as the first photolithographic pattern on a wafer substrate by a second demagnification using the second optical reticle, and the microscopic pattern having a third fiducial alignment mark corresponding to the second fiducial alignment mark; and
wherein multiplication of the first magnification by the first demagnification by the second demagnification equals one.

2. The method according to claim 1, wherein the digital transformation comprises a process of optical proximity correction.

3. The method according to claim 1, wherein the transparent substrate is a quartz class wafer.

4. The method according to claim 1, wherein the second optical reticle is a micro to nano scale opaque thin film pattern made of one or any combination of chrome, chrome oxide and chrome oxynitride, titanium, titanium nitride, rubidium, molybdenum and molybdenum silicide, tantalum and tantalum nitride, tungsten, and ruthenium.

5. The method according to claim 1, wherein the first optical reticle comprises a phase shifter in a thin film microstructure.

6. The method according to claim 5, wherein the phase shifter is made of opaque material of one or any combination of chrome, chrome oxide and chrome oxynitride, titanium, titanium nitride, tantalum and tantalum nitride.

7. The method according to claim 1, wherein the first photolithographic pattern comprises a first clear-field photolithographic pattern and a first dark-field photolithographic pattern, the second photolithographic pattern comprises a second clear-field photolithographic pattern and a second dark-field photolithographic pattern, the step of converting the first photolithographic pattern to the second photolithographic pattern comprises: converting the first clear-field photolithographic pattern to the second clear-field photolithographic pattern, and converting the first dark-field photolithographic pattern to the second dark-field photolithographic pattern;
the step of producing the first optical reticle corresponding to the second photolithographic pattern comprises: producing a first clear-field optical reticle corresponding to the second clear-field photolithographic pattern and a first dark-field optical reticle corresponding to the second dark-field photolithographic pattern, the first clear-field optical reticle having a first clear-field fiducial alignment mark, and the first dark-field optical reticle having a first dark-field fiducial alignment mark;
the step of fabricating the second optical reticle corresponding to the first optical reticle comprises: fabricating the second clear-field optical reticle corresponding to the first clear-field optical reticle and the second dark-field optical reticle corresponding to the first dark-field optical reticle; the second clear-field optical reticle and the second dark-field optical reticle being not overlapped and disposed one next to another side by side; the second clear-field optical reticle having a second clear-field fiducial alignment mark, and the second dark-field optical reticle having a second dark-field fiducial alignment mark.

8. The method according to claim 7, wherein the step of fabricating the microscopic pattern of same dimension as the first photolithographic pattern on the wafer substrate by the second demagnification using the second optical reticle comprises:
fabricating a clear-field microscopic pattern of same dimension as the first clear-field photolithographic pattern on a first wafer substrate by a second photolithography in the second demagnification using the second clear-field optical reticle; and the clear-field microscopic pattern having a third clear-field fiducial alignment mark corresponding to the second clear-field fiducial alignment mark; and
fabricating a dark-field microscopic pattern of same dimension as the first dark-field photolithographic pattern on a second wafer substrate by a second photolithography in the second demagnification using the second dark-field optical reticle; and the dark-field microscopic pattern having a third dark-field fiducial alignment mark corresponding to the second dark-field fiducial alignment mark.

9. The method according to claim 8, wherein the digital transformation and/or the second photolithography comprises a process of optical proximity correction.

10. The method according to claim 7, wherein the step of fabricating the microscopic pattern of same dimension as the first photolithographic pattern on the wafer substrate by the second demagnification using the second optical reticle comprises:
fabricating a clear-field microscopic pattern of same dimension as the first clear-field photolithographic pattern on the wafer substrate by a second photolithography in the second demagnification using the second clear-field optical reticle; and the clear-field microscopic pattern having a third clear-field fiducial alignment mark corresponding to the second clear-field fiducial alignment mark; and
fabricating a dark-field microscopic pattern of same dimension as the first dark-field photolithographic pattern on the wafer substrate by a third photolithography in the second demagnification using the second dark-field optical reticle; and the dark-field microscopic pattern having a fourth dark-field fiducial alignment mark to the second dark-field fiducial alignment mark; the dark-field microscopic pattern being disposed above or under the clear-field microscopic pattern horizontally overlapped; the third clear-field fiducial alignment mark and the fourth dark-field fiducial alignment mark being vertically aligned.

11. The method according to claim 10, wherein the digital transformation, the second photolithography and/or the third photolithography comprises a process of optical proximity correction.
